(19) United States
(12) Patent Application Publication
(10) Pub. No.: US 2003/0042580 A1
(43) Pub. Date: Mar. 6, 2003

(54) Elimination of via-resistance-shift by increasing via size at a last level

(76) Inventors: Mark Hoinkis, Fishkill, NY (US); Erdem Kaltalioglu, Wappingers Falls, NY (US); Andrew Cowley, Wappingers Falls, NY (US); Michael Stetter, Munich (DE)

Correspondence Address: Infineon Technologies North America Corp., c/o Siemens Corporation, Intellectual Property Department, 186 Wood Avenue South, Iselin, NJ, 08830, US

(21) Appl. No.: 09/883,425

(22) Filed: Jun. 18, 2001

(51) Int. Cl. H01L 23/58

(52) U.S. Cl. 257/642

(57) ABSTRACT

Semiconductor devices and methods are disclosed which address resistance shift reliability problems. At least one conductive level is included which has first vias formed in an organic material. The first vias include first contacts formed therein having a first layout dimension. An organic dielectric layer is formed on the at least one conductive level including second vias. The second vias include second contacts formed therein having a second layout dimension greater than the first layout dimension. An inorganic dielectric layer is formed on the organic dielectric layer. The employing this structure resistance shift reliability is prevented.

### BACKGROUND

1. Technical Field

This disclosure relates to semiconductor fabrication, and more particularly, to a structure and method for reducing via-resistance shift when employing organic dielectric layers in semiconductor devices.

2. Description of the Related Art

Semiconductor devices employ metal layers for connecting electronic devices. Metal layers for semiconductors are electrically isolated from other metal lines and layers by employing dielectric layers therebetween. In one example, a dielectric layer is deposited on a semiconductor device and then is patterned to form trenches or holes therein. The trenches or holes are then filled with metal to provide interlevel connections or same level connections to various electrical components. These holes are referred to as vias and the metal filling the vias may be called contacts or in some cases vias.

Metal lines formed in such trenches typically include Aluminum. Aluminum is sufficient for many applications; however, other materials, such as copper, provide higher conductivity. Further, for logic applications, Aluminum may be unsuitable especially in smaller groundrule designs.

Higher conductivity is particularly useful in semiconductor devices with smaller line widths. As the line width decreases, resistance increases. Providing a material, like copper, which has a higher conductivity, may compensate for this.

Copper also has several shortcomings, however. The dielectric layers employed for isolating copper often include oxygen, for example, silicon oxides. Electrical properties of copper degrade significantly when oxidized. Diffusion barriers employed between the dielectric layer and the copper, especially for smaller line widths, reduce the cross-sectional area of the copper in the trench since these diffusion barrier layers occupy space. Oxidation and reduced line width due to diffusion barriers increases the resistance of the metal line for a given line width. These vias are especially vulnerable to resistance shifting due to thermal cycling caused by semiconductor chip processing or thermal cycling due to operation of the semiconductor device. Since thermal cycling also causes high shear stress through interconnect interfaces, (especially in systems with high coefficients of thermal expansion) such as through vias, connections between metal layers may be disrupted, broken or intermittent.

Back-end-of-line (BEOL) metallizations (upper metal layers) are particularly susceptible to resistance shift and mechanical stress due to thermal cycling caused by the thermal expansion coefficient mismatch between copper and dielectric materials. Such designs include contacts or vias, all of which are formed with minimum feature sizes. With this structure, a via-resistance shift results.

To improve the BEOL performance, low dielectric constant (low-k) dielectric materials are considered for the next generation of copper dual damascene integration. These low-k materials have lower mechanical (e.g., low hardness and modulus) properties, which is a major reliability concern. In addition, some organic low-k materials, such as SILK (a trademark of DOW Chemical) have a high thermal expansion coefficient. This material property mismatch between, e.g., copper and SILK induces higher mechanical stress on via structures. These materials are not suitable in BEOL processing.

Therefore, a need exists for structures and methods for reducing or eliminating resistance shift in metallization layers of semiconductor devices.

### SUMMARY OF THE INVENTION

The present invention includes a last conductive level built in an organic dielectric layer, such as SILK or any other dielectric layer with similar mechanical properties prior to an oxide level. The last conductive metal includes vias, which are larger than a minimum ground rule dimension to avoid the via-resistance-shift reliability problems. In preferred embodiments, minimum ground rule vias are employed in all dielectric levels except the last level before an oxide level. In this last level, the vias, which are larger than ground rule, are employed.

Semiconductor devices and methods are disclosed which address resistance shift reliability problems. At least one conductive level is included which has first vias formed in an organic material. The first vias include first contacts formed therein having a first layout dimension. An organic dielectric layer is formed on the at least one conductive level including second vias. The second vias include second contacts formed therein having a second layout dimension greater than the first layout dimension. An oxide dielectric layer is formed on the organic dielectric layer. The employing this structure resistance shift reliability is prevented.

These and other objects, features and advantages of the present invention will become apparent from the following detailed description of illustrative embodiments thereof, which is to be read in connection with the accompanying drawings.

### BRIEF DESCRIPTION OF DRAWINGS

This disclosure will present in detail the following description of preferred embodiments with reference to the following figures wherein:

FIG. 1 is a cross-sectional view of a semiconductor device showing an organic dielectric layer patterned in accordance with the present invention;

FIG. 2 is a cross-sectional view of the semiconductor device of FIG. 1 showing a conductive material deposited to form contacts and conductive lines in accordance with the present invention;

FIG. 3 is a cross-sectional view of the semiconductor device of FIG. 2 showing a last organic dielectric layer patterned in accordance with the present invention;

FIG. 4 is a cross-sectional view of the semiconductor device of FIG. 3 showing a conductive material deposited to form contacts and conductive lines in accordance with the present invention; and

FIG. 5 is a cross-sectional view of the semiconductor device of FIG. 4 showing an inorganic dielectric layer deposited in accordance with the present invention.

### DETAILED DESCRIPTION OF PREFERRED EMBODIMENTS

The present invention provides methods for addressing resistance shift in metallization layers of semiconductor devices. The structures of the present invention reduce resistance shifting experienced due to thermal cycling as a result of processing or testing a semiconductor device. The present invention is particularly useful for back-end-of-line (BEOL) metallizations.

Highly conductive materials, such as for example copper and its alloys, are susceptible to oxidation and corrosion. To avoid contact between these highly conductive materials and oxygen, organic dielectric layers are passivated by using silicon oxides for protection. Liners are also placed in the metal line trenches to prevent diffusion of oxygen into the highly conductive material and to prevent outdiffusion of the highly conductive material into the surrounding dielectric.

Organic dielectrics, such as, for example, SILK (Trademark of DOW Chemical), polyimide or other low-k materials may be employed to avoid the use of silicon containing dielectrics. However, organic dielectrics are susceptible to thermal changes (e.g., due to high thermal expansion coefficient mismatches between dielectrics and conductors), which can cause resistance shifting. The present invention provides a structure, which reduces resistance shifting in vias by increasing the size of vias formed in a last layer of the organic dielectric layer. Then, an inorganic dielectric layer is formed over the last organic dielectric layer. Testing performed by the inventors has shown that significant stress reductions are achieved in the structure of the present invention. In turn, this reduces or eliminates failures due to resistance shifting.

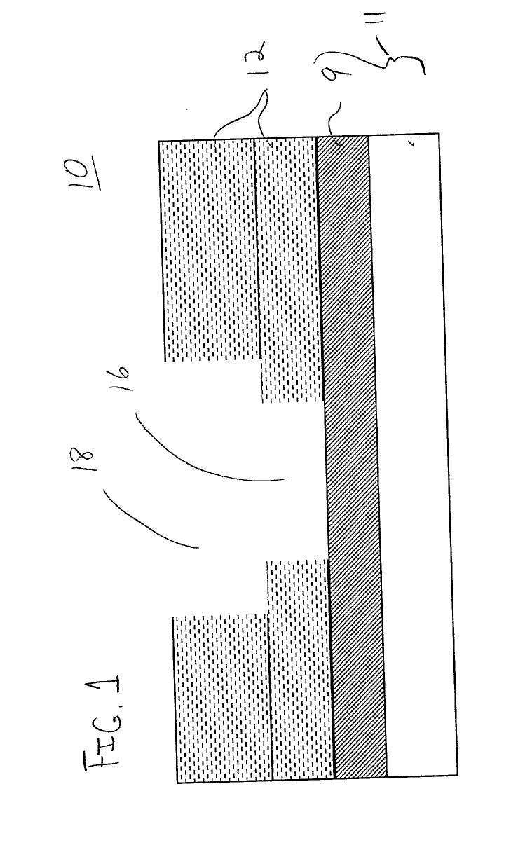

Referring now in specific detail to the drawings in which like reference numerals identify similar or identical elements throughout the several views, and initially to FIG. 1, a partially fabricated semiconductor device 10 is shown. Device 10 may include a dynamic random access memory (DRAM), and static random access memory (SRAM), or any other device, which employs metallization levels.

Underlying layers 11 of device 10 may include a substrate, dielectric layers, components, metallizations (9), etc. Dielectric layers 12 are formed on underlying layers 11. Dielectric layers 12 preferably include an organic dielectric material, for example, SILK, polyimide, etc.

Layer 12 is patterned to form via holes 16 and/or trenches 18. Via holes 16 and trenches 18 may include damascene or dual damascene structures. It is to be understood that dielectric layers 12 may be formed as a single dielectric layer or a plurality of dielectric layers.

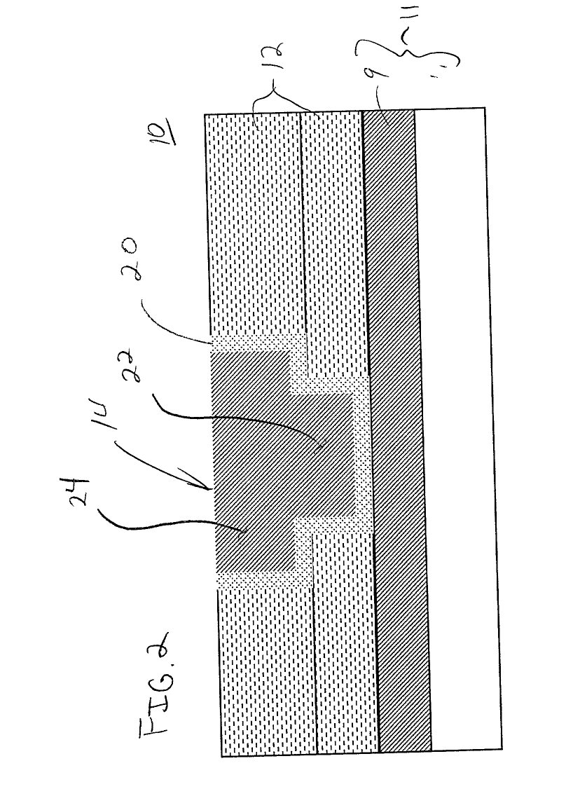

Referring to FIG. 2, via holes 16 and trenches 18 (FIG. 1) may be lined with a liner layer 20. Liner layer 20 functions as a diffusion barrier and may include materials, such as, for example, Ti, TiN, Ta and/or TaN.

Conductive materials 14 form contacts 22 and conductive lines 24. Contacts 22 and lines 24 are preferably maintained at a groundrule dimension or minimum feature size (F). Contacts 22 preferably include a width and/or depth about a minimum feature size. The minimum feature size may be about 0.2 microns or less. Contacts 22 in underlying layer 11 and dielectric layer 12 preferably include dimensions with the minimum feature size.

Contacts 22 and lines 24 preferably include a highly conductive material, such as copper, aluminum, tungsten or alloys thereof. Contacts 22 and lines 24 may be formed in a single process step (dual damascene) or individual process steps (damascene) by know deposition processes, for example chemical vapor deposition (CVD), physical vapor deposition (PVD), ion physical vapor deposition (IPVD), etc.

It has been found by the inventors that, in conventional devices, the resistance of fully-landed vias (e.g., fully landed on lower metallizations 9) tends to increase after additional processing steps or during thermal-stress testing after a semiconductor wafer is completed. The severity of this via-resistance shift problem increases with decreasing via-size. The present invention prevents via-resistance shift, as will be described below.

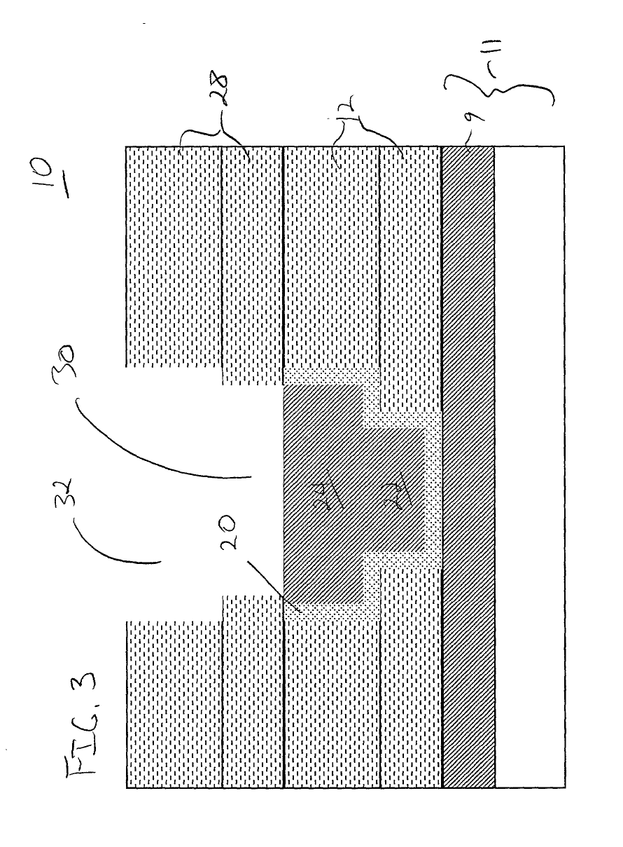

Referring to FIG. 3, dielectric layers 28 are formed and patterned on dielectric layer 12. Via holes 30 and trenches 32 are formed in accordance with the present invention. Via holes 30 are formed to dimensions greater than the minimum feature size of device 10. In one embodiment, via holes 30 are preferably formed with dimensions, which are 20% to 100% greater than the minimum feature size or the size of vias 16. It is to be understood that dielectric layers 28 may be formed as a single dielectric layer or a plurality of dielectric layers.

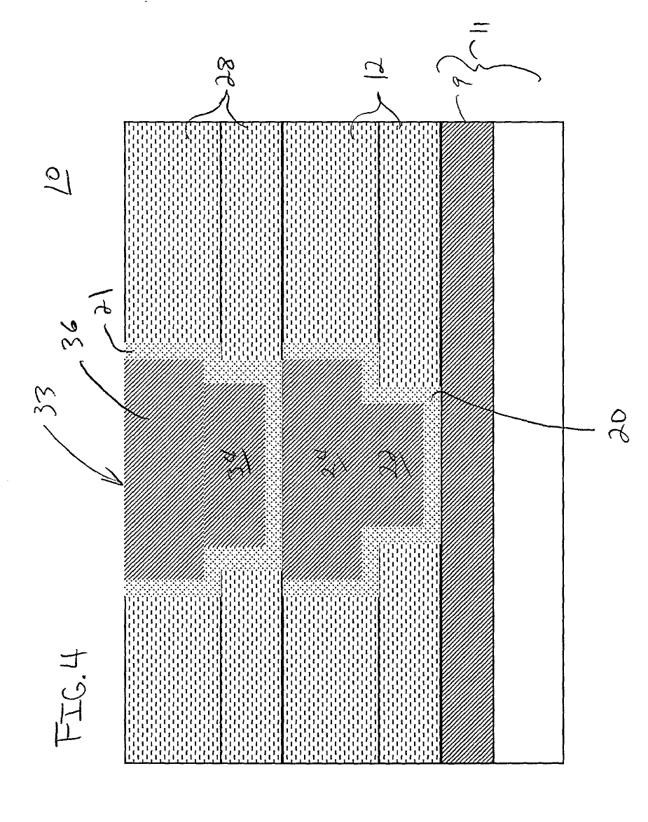

Referring to FIG. 4, a liner layer 21 may be formed in via holes 30 and trenches 32. Liner layer 21 is preferably the same as liner layer 20. A conductive material 33 is deposited in via holes 30 (FIG. 3) to form contacts 34. Contacts 34 are larger than the layout dimensions of the previous layer's contacts 22. In a preferred embodiment, the previous layer's contacts 22 include minimum feature size layout dimension. Contacts 34 are larger than the minimum feature size layout dimensions to reduce or eliminate stress, which often results in resistance shifting. Conductive material 33 may also include conductive lines 36. Dielectric layer 28 represents a last metallization layer in the structure of device 10.

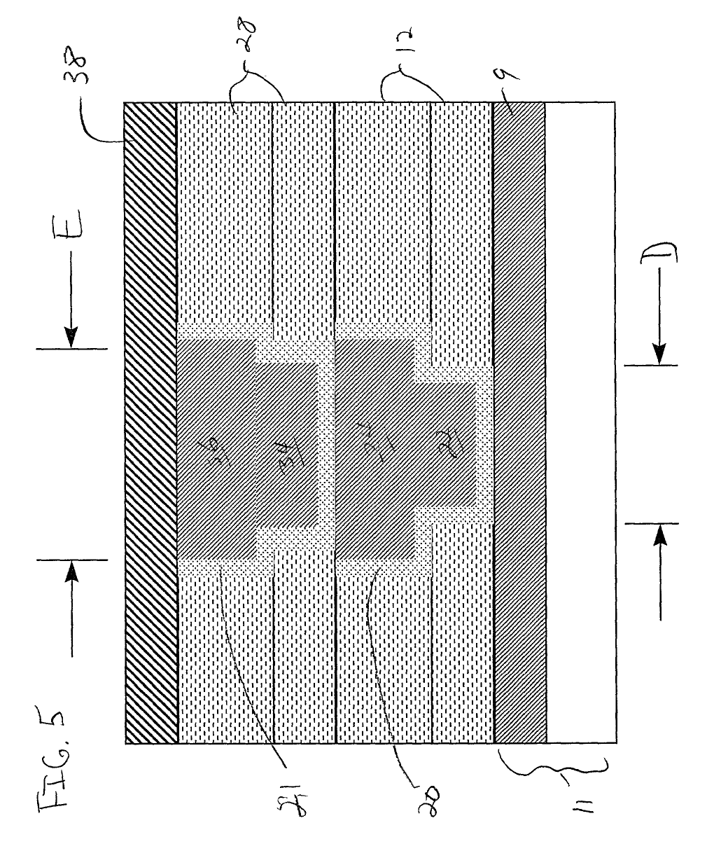

Referring to FIG. 5, a dielectric layer 38 is formed over conductive lines 36 and/or contacts 34. Dielectric layer 38 (passivation layer over the metallization level(s)) preferably includes an inorganic material, such as, an oxide material, for example, silicon dioxide. Other dielectric materials may be employed, such as a nitride.

The inventors have found that forming an oxide layer on organic dielectric layers increases compressive stresses in the organic layers especially during thermal cycling conditions. Although employing SILK or other organic materials is advantageous for the last passivation layer, an oxide material for dielectric layer 38 provides stability and reliable performance over time.

In one embodiment, dielectric layers 28 and 12 employ organic materials such as SILK and dielectric layer 38 includes an oxide. The resistance in contacts 34 may be observed to increase after the oxide of layer 38 is formed.

Stress simulations performed by the inventors show that a compressive stress in contact 34 becomes higher when the subsequent level is built in oxide, rather than SILK. In accordance with the present invention; however, if the last conductor level formed in dielectric layers 28 includes an organic dielectric, via holes 30 (FIG. 3) and therefore contacts 34 are formed with an enlarged size (e.g., greater than the minimum via dimension), the via-resistance shift is overcome.

Thus, the present invention employs a preferred size D, for example, ground-rule sized vias, for levels built in organic dielectric layers up to the a last level prior to an oxide layer deposition. In the last level built in the organic dielectric, before the oxide level, an enlarged via size E is used (e.g., greater than F). By providing this structure, the via-resistance problem (resistance shifting) is reduced or eliminated. Dimensions D and E may be representative of the layout area (e.g., diameters for circular contacts or sides for a square or rectangular contacts) of the contacts or a single dimension of the contact (e.g., width).

Having described preferred embodiments for elimination of via-resistance-shift by increasing via size at a last level (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

What is claimed is:

1. A semiconductor device, comprising:
at least one conductive level including first vias formed in an organic material, the first vias including first contacts formed therein having a first layout area;
an organic dielectric layer formed on the at least one conductive level including second vias, the organic dielectric layer being a last metallization level of the semiconductor device, the second vias including second contacts formed therein having a second layout area greater than the first layout area; and
an inorganic dielectric layer formed on the organic dielectric layer.

2. The device as recited in claim 1, wherein the organic material includes SILK.

3. The device as recited in claim 1, wherein the organic dielectric layer includes SILK.

4. The device as recited in claim 1, wherein the first contacts include copper.

5. The device as recited in claim 1, wherein the second contacts include copper.

6. The device as recited in claim 1, wherein the first vias include a liner layer.

7. The device as recited in claim 1, wherein the second vias include a liner layer.

8. The device as recited in claim 1, wherein the second layout area includes a dimension which is greater than between 20% and 100% of a corresponding dimension for the first layout area.

9. The device as recited in claim 8, wherein the corresponding dimension for the first layout area includes a ground rule dimension.

10. The device as recited in claim 8, wherein the dimension for the second layout area includes a size greater than between 20% and 100% of the ground rule dimension.

11. A method for preventing resistance shifting in contacts of a semiconductor device, comprising the steps of:
patterning a first organic dielectric layer to form first vias and first trenches therein, the vias having a first layout dimension;
depositing a conductive material in the first vias and first trenches;
patterning a second organic dielectric layer to form second vias and second trenches therein, the second vias having a second layout dimension greater than the first layout dimension, the second organic dielectric layer being a last metallization level of the semiconductor device;
depositing a conductive material in the second vias and second trenches; and
forming an inorganic layer over the second organic dielectric layer.

12. The method as recited in claim 11, wherein the first organic layer includes SILK.

13. The method as recited in claim 11, wherein the second organic dielectric layer includes SILK.

14. The method as recited in claim 11, wherein the conductive material includes copper.

15. The method as recited in claim 11, further comprising the step of forming a liner layer before depositing the conductive material.

16. The method as recited in claim 11, wherein the second layout dimension is greater than between 20% and 100% of the first layout dimension.

17. The method as recited in claim 11, wherein the first layout dimension includes a ground rule dimension.

18. The method as recited in claim 11, wherein the second layout dimension includes a size greater than between 20% and 100% of the ground rule dimension.

19. The method as recited in claim 11, wherein the step of patterning the first organic dielectric layer includes forming one of damascene and dual damascene structures.

20. The method as recited in claim 11, wherein the step of patterning the second organic dielectric layer includes forming one of damascene and dual damascene structures.
